(19) United States
(12) Patent Application Publication
(10) Pub. No.: US 2010/0294332 A1
(43) Pub. Date: Nov. 25, 2010

(54) SOLAR CELL MODULE AND METHOD OF MANUFACTURING THE SAME

(75) Inventors: Toshio Yagiura, Kobe-shi (JP); Satoru Ogasahara, Ichinomiya-shi (JP); Kazushi Ishiki, Ichinomiya-shi (JP)

Correspondence Address: DITTHAVONG MORI & STEINER, P.C., 918 Prince Street, Alexandria, VA, 22314, US

(73) Assignee: Sanyo Electric Co., Ltd., Moriguch-shi (JP)

(21) Appl. No.: 12/727,650

(22) Filed: Mar. 19, 2010

(30) Foreign Application Priority Data
May 22, 2009 (JP) 2009-123695
Jun. 25, 2009 (JP) 2009-151349
Jun. 30, 2009 (JP) 2009-154469

(51) Int. Cl. H01L 31/042; H01L 31/00; H01L 21/28

(52) U.S. Cl. 136/244; 136/256; 438/73; 257/E21.158

(57) ABSTRACT

This solar cell module includes a plurality of conducting portions for electrically bonding solar cells and extraction electrodes to each other and a filler provided to cover the plurality of solar cells and the extraction electrodes. A plurality of first conducting portions arranged on the side of one end portion of a region where the plurality of solar cells are arranged and a plurality of second conducting portions arranged on the side of another end portion are asymmetrically arranged in plan view.

### CROSS-REFERENCE TO RELATED APPLICATIONS

The priority application numbers JP2009-154469, Solar Cell Module, Jun. 30, 2009, Toshio Yagiura, JP2009-151349, Thin-Film Solar Cell Module, Satoru Ogasahara, and JP2009-123695, Solar Cell Module, Kazushi Ishiki, upon which this patent application is based are hereby incorporated by reference.

### BACKGROUND OF THE INVENTION

1. Field of the Invention

The present invention relates to a solar cell module and a method of manufacturing the same, and more particularly, it relates to a solar cell module comprising a plurality of solder connection portions (conducting portions) and a method of manufacturing the same.

2. Description of the Background Art

A solar cell module comprising a plurality of solder connection portions is known in general.

For example, a solar cell module comprising a plurality of solar cells arranged to be adjacent to each other and electrically connected with each other, extraction electrodes provided on the sides of both end portions of the plurality of solar cells for extracting power from the solar cells and a plurality of solder connection portions (conducting portions) for connecting the solar cells and the extraction electrodes with each other is known. In this solar cell module, the plurality of solder connection portions are linearly arranged along the extensional direction of the extraction electrodes at constant intervals. A plurality of solder connection portions arranged on the sides of first end portions of the plurality of solar cells and a plurality of solder connection portions arranged on the sides of second end portions thereof are symmetrized with respect to centerlines of the plurality of solder connection portions arranged on the sides of the first end portions and the sides of the second end portions of the plurality of solar cells in plan view. In general, a filler made of ethylene vinyl acetate (EVA) or the like is provided on the surfaces of the solar cells. The surface of the filler is embossed (irregularized) for deaerating the space between the solar cells and the filler.

When the embossed filler (having an irregular surface) is arranged on the plurality of solar cells (the extraction electrodes and the solder connection portions) in the aforementioned solar cell module, however, the plurality of solder connection portions symmetrically arranged on the sides of the first end portions and the sides of the second end portions of the plurality of solar cells may fit into recess portions of the filler respectively, since irregularities resulting from the embossing are regularly provided in general. In this case, the solder connection portions block the recess portions of the filler for deaeration when the space between the solar cells and the filler is deaerated by vacuum lamination. Thus, the space cannot be sufficiently deaerated. Consequently, air bubbles may disadvantageously remain in the solar cell module.

### SUMMARY OF THE INVENTION

A solar cell module according to a first aspect of the present invention comprises a plurality of solar cells electrically connected with each other, extraction electrodes provided on the sides of both end portions of a region where the plurality of solar cells are arranged for extracting power generated in the plurality of solar cells, a plurality of conducting portions provided between the solar cells and the extraction electrodes along the extensional direction of the extraction electrodes for electrically bonding the solar cells and the extraction electrodes to each other and a filler provided to cover the plurality of solar cells and the extraction electrodes, while the plurality of conducting portions include a plurality of first conducting portions regularly provided and arranged on the side of one end portion of the region where the plurality of solar cells are arranged and a plurality of second conducting portions regularly provided and arranged on the side of another end portion of the region where the plurality of solar cells are arranged, and the plurality of first conducting portions and the plurality of second conducting portions are asymmetrically arranged with respect to a centerline between the plurality of first conducting portions and the plurality of second conducting portions in plan view.

A method of manufacturing a solar cell module according to a second aspect of the present invention comprises the steps of preparing a plurality of solar cells electrically connected with each other, forming extraction electrodes for extracting power generated in the plurality of solar cells on the sides of both end portions of a region where the plurality of solar cells are arranged respectively, forming a plurality of conducting portions for electrically bonding the solar cells and the extraction electrodes to each other between the solar cells and the extraction electrodes along the extensional direction of the extraction electrodes, and bringing the plurality of solar cells, the extraction electrodes and a filler into close contact with each other by arranging the filler to cover the plurality of solar cells and the extraction electrodes and thereafter performing lamination, while the plurality of conducting portions include a plurality of first conducting portions regularly provided and arranged on the side of one end portion of the region where the plurality of solar cells are arranged and a plurality of second conducting portions regularly provided and arranged on the side of another end portion of the region where the plurality of solar cells are arranged, and the step of bringing the plurality of solar cells, the extraction electrodes and the filler into close contact with each other includes a step of performing lamination while arranging the filler on the plurality of first conducting portions and the plurality of second conducting portions asymmetrically arranged with respect to a centerline between the plurality of first conducting portions and the plurality of second conducting portions in plan view.

A solar cell module according to a third aspect of the present invention comprises a substrate, a power generating portion consisting of a plurality of thin-film solar cells each including a surface electrode formed on the substrate, a photoelectric conversion layer formed on the surface electrode and a rear electrode formed on the photoelectric conversion layer, an electricity extraction portion including a connection portion connected to the thin-film solar cell positioned on an end portion of the power generating portion, an extraction electrode formed on the electricity extraction portion for extracting electricity generated by the power generating portion, a first fusion portion bonding the connection portion and the extraction electrode to each other and an extraction wire provided for extracting electricity from the extraction electrode and bonded to the extraction electrode by a second fusion portion on a position deviated from the first fusion portion not to overlap the first fusion portion in plan view.

A solar cell module according to a fourth aspect of the present invention comprises a substrate, a photoelectric conversion element provided on the substrate, an electrode arranged on a first surface of the photoelectric conversion element for collecting power, a wire connected to the electrode on the first surface of the photoelectric conversion element for extracting power from the electrode and an insulating adhesive member provided between the photoelectric conversion element and the wire, while a surface of the electrode connected with the wire and a surface of the insulating adhesive member opposed to the wire are flush with each other.

In the present invention, the term “flush” includes a state of “substantially flush” in the range for attaining an intended object of the present invention.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing the overall structure of an integrated thin-film solar cell module according to a first embodiment of the present invention;

FIG. 2 is a sectional view taken along the line 300-300 in FIG. 1;

FIG. 3 is a plan view showing the overall structure of a solar cell portion of the integrated thin-film solar cell module according to the first embodiment of the present invention;

FIG. 4 is a plan view showing the arrangement of solder connection portions of the integrated thin-film solar cell module according to the first embodiment of the present invention;

FIG. 5 is a sectional view taken along the line 310-310 in FIG. 4;

FIG. 6 is a sectional view taken along the line 320-320 in FIG. 4 before vacuum lamination;

FIG. 7 is a sectional view taken along the line 330-330 in FIG. 4 before the vacuum lamination;

FIG. 8 is a sectional view taken along the line 340-340 in FIG. 4 before the vacuum lamination;

FIG. 9 is a sectional view taken along the line 340-340 in FIG. 4 after the vacuum lamination;

FIG. 10 is a sectional view taken along the line 350-350 before the vacuum lamination;

FIG. 11 is a sectional view taken along the line 350-350 in FIG. 4 after the vacuum lamination;

FIG. 12 is a sectional view of one end portion of an integrated thin-film solar cell module according to a second embodiment of the present invention;

FIG. 13 is a sectional view of another end portion of the integrated thin-film solar cell module according to the second embodiment of the present invention;

FIG. 14 is a plan view showing the arrangement of solder connection portions of an integrated thin-film solar cell module according to a third embodiment of the present invention;

FIG. 15 is a plan view of an integrated thin-film solar cell module according to a fourth embodiment of the present invention as viewed from the rear surface side (opposite to an incidence side);

FIG. 16 is a sectional view taken along the line 500-500 in FIG. 15;

FIG. 17 is a sectional view taken along the line 510-510 in FIG. 15;

FIG. 18 is a sectional view taken along the line 520-520 in FIG. 15;

FIG. 19 is a sectional view showing a thin-film solar cell module according to a modification of the fourth embodiment of the present invention;

FIG. 20 is a top plan view of a solar cell module according to a fifth embodiment of the present invention;

FIG. 21 is a sectional view of the solar cell module according to the fifth embodiment taken along the line 800-800 in FIG. 20; and

FIG. 22 is a sectional view of the solar cell module according to the fifth embodiment taken along the line 850-850 in FIG. 20.

### DESCRIPTION OF THE PREFERRED EMBODIMENTS

Embodiments of the present invention are now described with reference to the drawings.

### First Embodiment

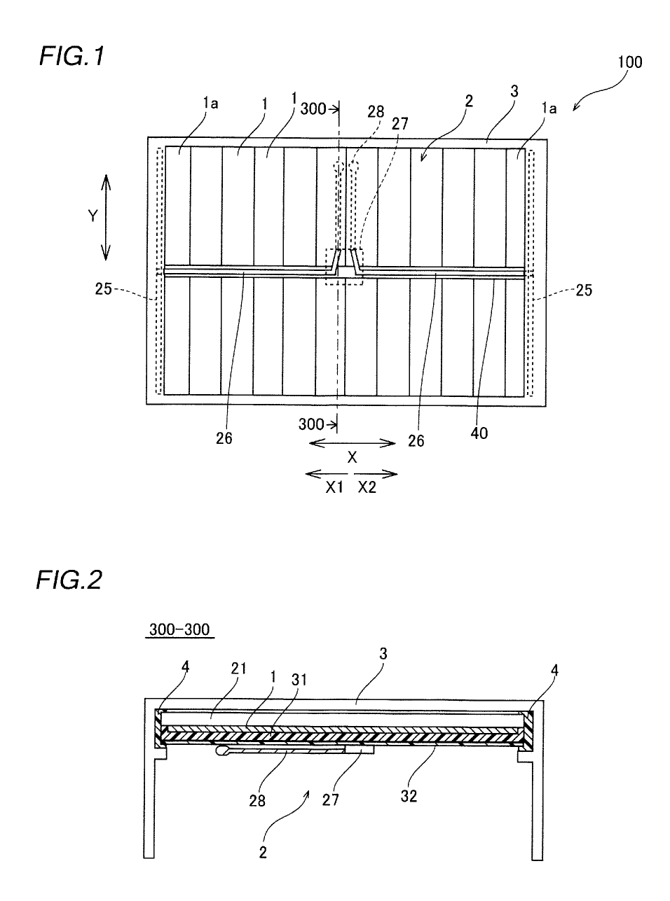

An integrated thin-film solar cell module 100 according to a first embodiment of the present invention is constituted of a solar cell portion 2 provided with a plurality of solar cells 1, an aluminum frame 3 and a rubber frame 4, as shown in FIGS. 1 and 2. The solar cell portion 2 is mounted on the aluminum frame 3 through the rubber frame 4.

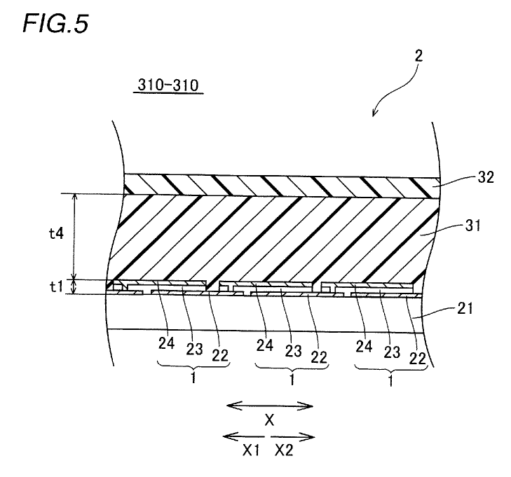

In the solar cells 1, surface electrodes 22 made of a transparent conductive oxide (TCO) such as tin oxide (SnO₂), zinc oxide (ZnO) or indium tin oxide (ITO) having conductivity and light transmission properties are formed on a glass substrate 21, as shown in FIG. 5. The surface electrodes 22 are plurally formed at prescribed intervals. Semiconductor layers 23 made of a p-i-n amorphous silicon semiconductor are formed on the surfaces of the surface electrodes 22. The semiconductor layers 23 are constituted of p-type hydrogenated amorphous silicon carbide (a-SiC:H) layers, i-type hydrogenated amorphous silicon (a-Si:H) layers and n-type hydrogenated amorphous silicon layers, for example. Rear electrodes 24 made of a metallic material mainly composed of silver (Ag) having conductivity are formed on the surfaces of the semiconductor layers 23. The surface electrodes 22, the semiconductor layers 23 and the rear electrodes 24 constitute the solar cells 1 each having a thickness t1 of about 1 μm. The rear electrodes 24 of first ones of the solar cells 1 adjacent to each other and the surface electrodes 22 of second ones of these solar cells 1 are electrically connected with each other. Thus, the plurality of solar cells 1 are electrically connected in series with each other and integrated on the glass substrate 21.

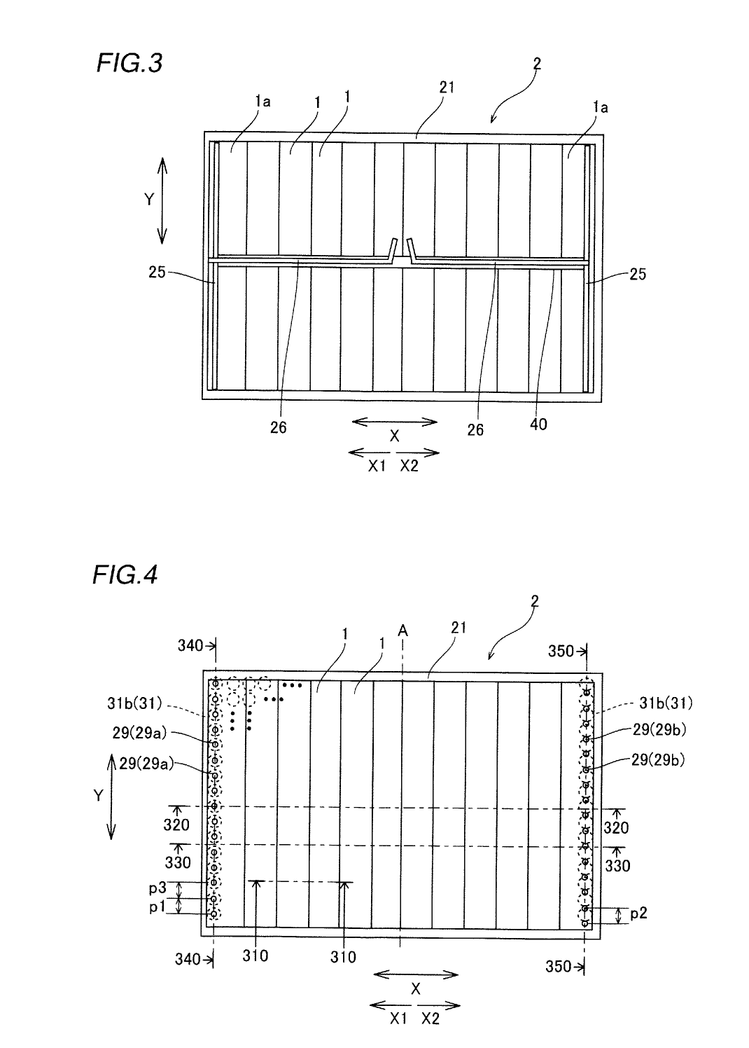

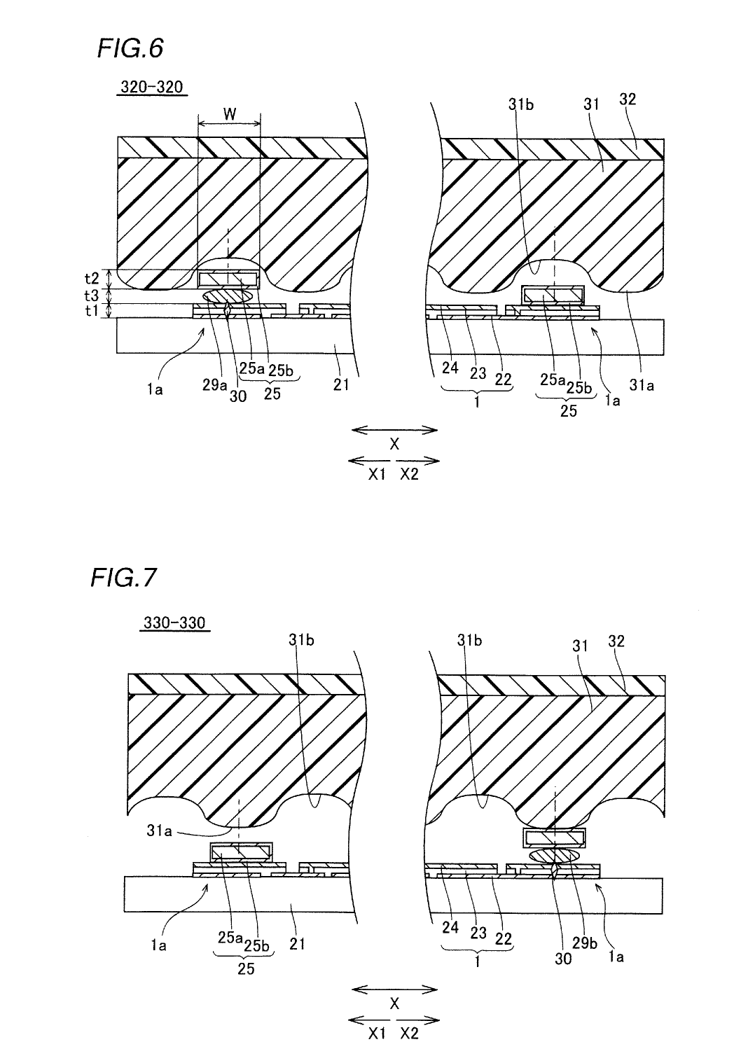

As shown in FIG. 3, first extraction electrodes 25 and second extraction electrodes 26 for extracting power from the plurality of solar cells 1 connected in series with each other are provided on the sides of end portions of the plurality of solar cells 1 along arrows X1 and X2 respectively. The first extraction electrodes 25 are formed to extend along a direction Y in plan view. The second extraction electrodes 26 are formed to extend along a direction X. The first extraction electrodes 25 have structures obtained by coating the peripheries of copper foils 25a with tin films 25b as shown in FIG. 6, and the second extraction electrodes 26 also have similar structures. Each of the first extraction electrodes 25 has a width W of about 2 mm and a thickness t2 of about 100 μm. Each of the second extraction electrodes 26 has a width of about 5 mm and a thickness of about 100 μm. The first extraction electrodes 25 are examples of the “extraction electrodes” in the present invention.

As shown in FIG. 1, the second extraction electrodes 26 are mounted on the surfaces of the solar cells 1 through an insulating tape 40. The second extraction electrodes 26 are bent in the vicinity of a central portion of the thin-film solar cell module 100. The bent portions of the second extraction electrodes 26 are covered with a terminal box 27. The second extraction electrodes 26 are connected to output cables 28.

As shown in FIG. 4, the solar cells 1 (surface electrodes 22) and the first extraction electrodes 25 are electrically connected with each other through a plurality of solder connection portions 29 each having a thickness t3 (see FIG. 6) of about 100 μm. The plurality of solder connection portions 29 are linearly provided along the extensional direction (direction Y) of the first extraction electrodes 25. The pitch p1 of a plurality of solder connection portions 29 (solder connection portions 29a) provided on the side of the solar cells 1 along arrow X1 and the pitch p2 of a plurality of solder connection portions 29 (solder connection portions 29b) provided on the side of the solar cells 1 along arrow X2 are substantially equal to each other, and at least about 20 mm and not more than about 30 mm. The solder connection portions 29 are examples of the “conducting portions” in the present invention. The solder connection portions 29a and 29b are examples of the “second conducting portions” and the “first conducting portions” in the present invention respectively.

According to the first embodiment, the solder connection portions 29b arranged along arrow X2 are deviated from the solder connection portions 29a arranged along arrow X1, so that central portions of the solder connection portions 29b arranged along arrow X2 do not align with central portions of recess portions 31b (are opposed to projecting portions 31a) of a filler 31 described later in plan view. In other words, the plurality of solder connection portions 29a provided on the side of the solar cells 1 along arrow X1 and the plurality of solder connection portions 29b provided on the side of the solar cells 1 along arrow X2 are asymmetrically provided with respect to a centerline A between the solder connection portions 29a and the solder connection portions 29b. The plurality of solder connection portions 29b provided on the side of the solar cells 1 along arrow X2 are deviated from the plurality of solder connection portions 29a provided on the side of the solar cells 1 along arrow X1 by substantially half the pitch p3 of the recess portions 31b (projecting portions 31a) of the filler 31 in the direction Y.

As shown in FIGS. 6 and 7, the solder connection portions 29 are connected to the surface electrodes 22 through bonding portions 30. Solar cells la located under the first extraction electrodes 25 do not contribute to power generation. FIGS. 6 and 7 show a state before vacuum lamination described later. The space between the filler 31 and the solar cells 1 is so deaerated as to bring the filler 31 into close contact with the surfaces of the solar cells 1, as shown in FIG. 5.

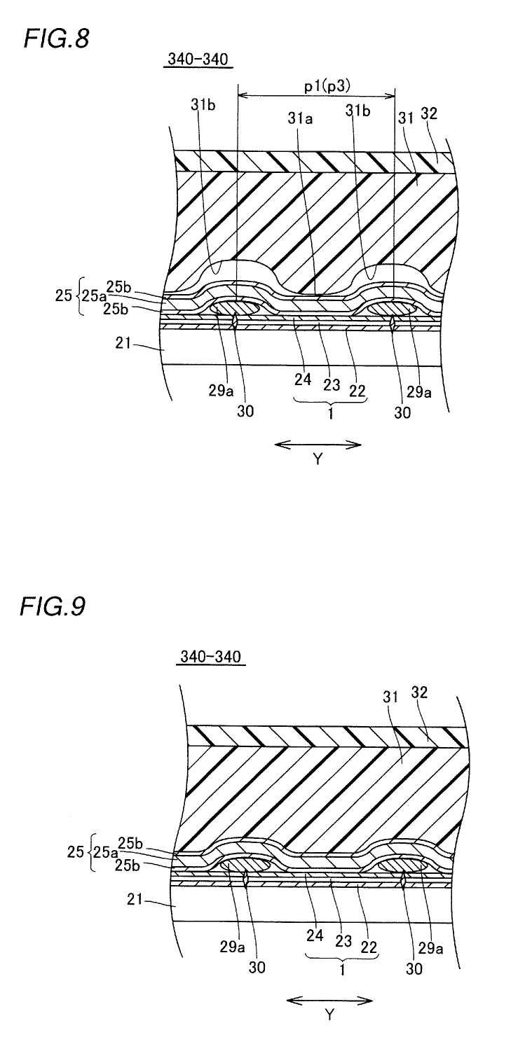

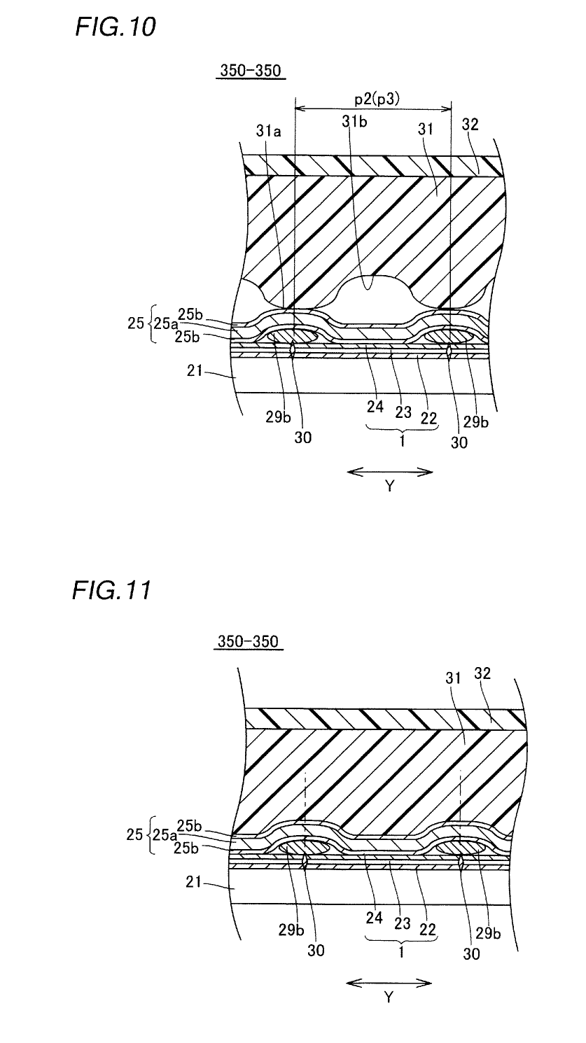

As shown in FIG. 5, the filler 31, made of ethylene vinyl acetate (EVA) or the like, having a thickness t4 of about 600 μm is provided on the surfaces of the solar cells 1. The surface of the filler 31 closer to the solar cells 1 is embossed and provided with a plurality of irregularities (the projecting portions 31a and the recess portions 31b), as shown in FIG. 6. The recess portions 31b (projecting portions 31a) of the filler 31 are regularly arranged (in the form of a matrix) on the surface of the filler 31 closer to the solar cells 1 at regular intervals, as shown in FIG. 4. According to the first embodiment, the pitch p1 (p2) of the solder connection portions 29 is rendered integral times the pitch p3 of the projecting portions 31a or the recess portions 31b of the filler 31. FIGS. 8 and 10 show a case where the pitch p1 (p2) of the solder connection portions 29 is equal to (one time as long as) the pitch p3 of the projecting portions 31a or the recess portions 31b, in order to simplify the illustration. The filler 31 may alternatively be made of resin such as EEA, PVB, silicon, urethane, acrylic or epoxy, for example, in place of EVA.

As hereinabove described, the plurality of solder connection portions 29b provided on the side of the solar cells 1 along arrow X2 are deviated from the plurality of solder connection portions 29a provided on the side of the solar cells 1 along arrow X1 by substantially half the pitch p3 of the recess portions 31b (projecting portions 31a) of the filler 31 in the direction Y, whereby the central portions of the solder connection portions 29a arranged along arrow X1 substantially align with the central portions of the recess portions 31b of the filler 31, as shown in FIG. 6 (section taken along the line 320-320 in FIG. 4). Further, central portions of the first extraction electrodes 25 on regions not provided with the solder connection portions 29b arranged along arrow X2 also substantially align with the central portions of the recess portions 31b of the filler 31. On the other hand, central portions of the first extraction electrodes 25 on regions not provided with the solder connection portions 29a arranged along arrow X1 substantially align with the central portions of the projecting portions 31a of the filler 31, as shown in FIG. 7 (section taken along the line 330-330 in FIG. 4). Further, the central portions of the solder connection portions 29b arranged along arrow X2 also substantially align with the central portions of the projecting portions 31a of the filler 31.

As hereinabove described, the plurality of solder connection portions 29b provided on the side of the solar cells 1 along arrow X2 are deviated from the plurality of solder connection portions 29a provided on the side of the solar cells 1 along arrow X1 by substantially half the pitch p3 of the recess portions 31b (projecting portions 31a) of the filler 31 in the direction Y, whereby the central portions of the plurality of solder connection portions 29a substantially align with the central portions of the recess portions 31b of the filler 31 respectively in plan view on the side of the thin-film solar cell module 100 along arrow X1, as shown in FIG. 4 and FIG. 8 (section taken along the line 340-340 in FIG. 4). In other words, the plurality of solder connection portions 29a are opposed to the recess portions 31b of the filler 31 respectively. On the side of the thin-film solar cell module 100 along arrow X2, on the other hand, the central portions of the plurality of solder connection portions 29b substantially align with the central portions of the projecting portions 31a of the filler 31 respectively in plan view, as shown in FIGS. 4 and 10 (section taken along the line 350-350 in FIG. 4). In other words, the plurality of solder connection portions 29b are opposed to the projecting portions 31a of the filler 31 respectively. FIGS. 8 and 10 show the state before the vacuum lamination described later. The space between the filler 31 and the solar cells 1 is so deaerated by the vacuum lamination as to bring the filler 31 into close contact with the surfaces of the solar cells 1, as shown in FIG. 9 (section taken along the line 340-340 in FIG. 4) and FIG. 11 (section taken along the line 350-350 in FIG. 4). A back sheet 32 is provided on the surface of the filler 31, as shown in FIG. 5 (section taken along the line 310-310 in FIG. 4). The back sheet 32 is constituted of a resin film of PET, PEN, ETFE, PVDF, PCTFE, PVF or PC, for example. Alternatively, the back sheet 32 may have a structure obtained by holding a metal foil between resin films or the like, or may be constituted of a metal plate (steel plate) of SUS or galvarium.

A manufacturing process for the thin-film solar cell module 100 according to the first embodiment is now described with reference to FIGS. 4 to 11.

First, the solar cells 1 consisting of the surface electrodes 22 made of the transparent conductive oxide (TCO) such as tin oxide (SnO₂), zinc oxide (ZnO) or indium tin oxide (ITO), the semiconductor layers 23 made of the p-i-n amorphous silicon semiconductor and the rear electrodes 24 made of the conductive material are formed on the surface of the glass substrate 21, as shown in FIG. 5. The semiconductor layers 23 are constituted of the p-type hydrogenated amorphous silicon carbide (a-SiC:H) layers, the i-type hydrogenated amorphous silicon (a-Si:H) layers and the n-type hydrogenated amorphous silicon layers, for example. The manufacturing process for the solar cells 1 is similar to that for conventional solar cells.

Then, the bonding portions 30 and the solder connection portions 29 (29a and 29b) are melted with an ultrasonic soldering iron on the surfaces of the solar cells la not contributing to power generation, as shown in FIG. 6 (section taken along the line 320-320 in FIG. 4) and FIG. 7 (section taken along the line 330-330 in FIG. 4). Thus, the bonding portions 30 are bonded to the surface electrodes 22. Then, the first extraction electrodes 25 are arranged on the solder connection portions 29, and bonded thereto. Further, the second extraction electrodes 26 are arranged on the first extraction electrodes 25, and bonded thereto.

The plurality of solder connection portions 29b provided on the side of the solar cells 1 along arrow X2 are deviated from the plurality of solder connection portions 29a provided on the side of the solar cells 1 along arrow X1 by substantially half the pitch p3 of the recess portions 31b (projecting portions 31a) of the filler 31 in the direction Y, as shown in FIG. 4. Then, the filler 31 is arranged on the surfaces of the solar cells 1 (first extraction electrodes 25). At this time, the filler 31 is so arranged that the central portions of the solder connection portions 29a arranged along arrow X1 substantially align with the central portions of the recess portions 31b of the filler 31 and the central portions of the first extraction electrodes 25 on the regions not provided with the solder connection portions 29a arranged along arrow X2 substantially align with the central portions of the recess portions 31b of the filler 31, as shown in FIG. 6. Further, the filler 31 is so arranged that the central portions of the first extraction electrodes 25 on the regions not provided with the solder connection portions 29a arranged along arrow X1 substantially align with the central portions of the projecting portions 31a of the filler 31 and the central portions of the solder connection portions 29b arranged along arrow X2 substantially align with the central portions of the projecting portions 31a of the filler 31, as shown in FIG. 7.

The solder connection portions 29a provided along arrow X1 (see FIG. 4) are so arranged that the central portions thereof substantially align with the central portions of the recess portions 31b of the filler 31, as shown in FIG. 8. On the other hand, the solder connection portions 29b provided along arrow X2 (see FIG. 4) are so arranged that the central portions thereof substantially align with the central portions of the projecting portions 31a of the filler 31, as shown in FIG. 10. Then, the vacuum lamination is so performed as to bring the filler 31 and the solar cells 1 as well as the first extraction electrodes 25 into close contact with each other, as shown in FIGS. 5, 9 and 11. In the state where the central portions of the solder connection portions 29b substantially align with the central portions of the projecting portions 31a of the filler 31 as shown in FIG. 10, the space between the filler 31 and the solar cells 1 is more easily deaerated than the state where the central portions of the solder connection portions 29a substantially align with the central portions of the recess portions 31b of the filler 31 as shown in FIG. 8, due to increase in the distance (space) between the filler 31 and the first extraction electrodes 25. Thereafter the back sheet 32 consisting of a resin film of PET, PEN, ETFE, PVDF, PCTFE, PVF or PC, having a structure obtained by holding a metal foil between resin films or consisting of a metal plate (steel plate) of SUS or galvarium, for example, is formed on the surface of the filler 31. Thus, the solar cell portion 2 is completed, and mounted on the aluminum frame 3 through the rubber frame 4, as shown in FIG. 2.

The thin-film solar cell module 100 according to the first embodiment of the present invention can attain the following effects:

(1) The plurality of solder connection portions 29b included in the plurality of solder connection portions 29 are so arranged that the central portions thereof do not align with the central portions of the recess portions 31b of the filler 31 in plan view. Thus, the solder connection portions 29 can be inhibited from blocking the recess portions 31b of the filler 31 for deaerating the space between the filler 31 and the solar cells 1 in the vacuum lamination, dissimilarly to a case where the central portions of all solder connection portions 29 align with the central portions of the recess portions 31b of the filler 31. Consequently, air bubbles can be inhibited from remaining in the thin-film solar cell module 100 due to insufficient vacuum lamination (deaeration).

(2) The solder connection portions 29b included in the plurality of solder connection portions 29 are deviated from the solder connection portions 29a opposed to the recess portions 31b of the filler 31, to be opposed to the projecting portions 31a of the filler 31. Thus, the solder connection portions 29 are inhibited from being entirely opposed to the recess portions 31b of the filler 31, whereby the solder connection portions 29 can be reliably inhibited from blocking the recess portions 31b of the filler 31 for deaerating the space between the filler 31 and the solar cells 1 in the vacuum lamination.

(3) The plurality of solder connection portions 29a provided on the side of the solar cells 1 along arrow X1 and the plurality of solder connection portions 29b provided on the side of the solar cells 1 along arrow X2 are asymmetrically provided with respect to the centerline A between the solder connection portions 29a and the solder connection portions 29b. Thus, the solder connection portions 29 can be reliably inhibited from blocking the recess portions 31b of the filler 31 for deaerating the space between the filler 31 and the solar cells 1 in the vacuum lamination, dissimilarly to a case where the solder connection portions 29a and the solder connection portions 29b are symmetrically provided with respect to the centerline A.

(4) The plurality of solder connection portions 29b provided on the side of the solar cells 1 along arrow X2 are deviated from the solder connection portions 29a provided along arrow X1 by substantially half the pitch p3 of the recess portions 31b (projecting portions 31a) of the filler 31. Thus, the solder connection portions 29b and the solder connection portions 29a can be easily opposed to the projecting portions 31a and the recess portions 31b of the filler 31 respectively.

### Second Embodiment

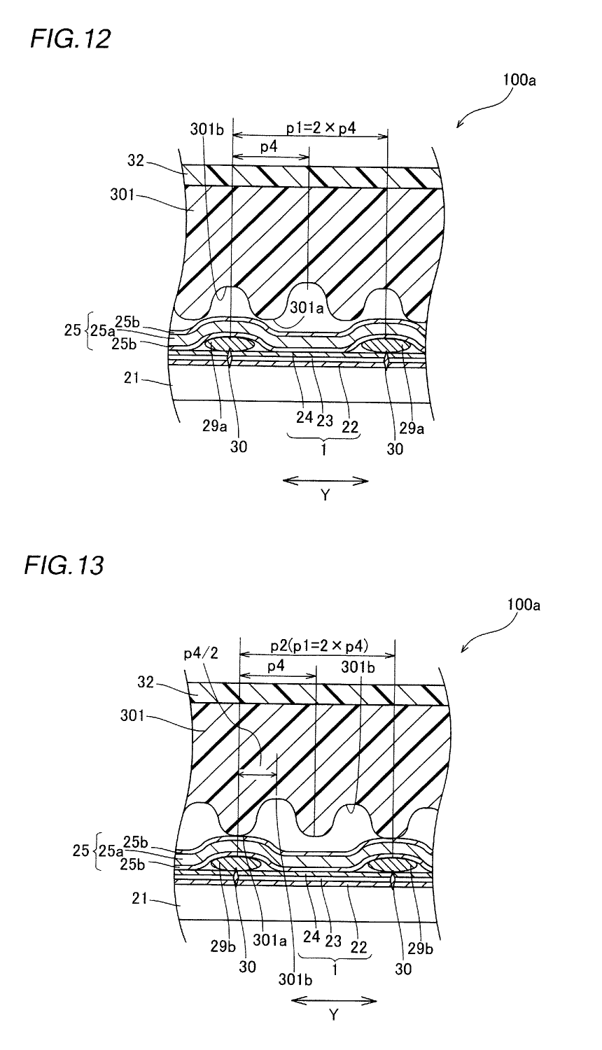

A thin-film solar cell module 100a according to a second embodiment of the present invention is now described with reference to FIGS. 12 and 13. In the thin-film solar cell module 100a according to the second embodiment, the pitch p4 of recess portions 301b (projecting portions 301a) of a filler 301 is different from the pitch p1 (p2) of solder connection portions 29, dissimilarly to the aforementioned first embodiment in which the pitch p3 of the recess portions 31b (projecting portions 31a) of the filler 31 is substantially equal to the pitch p1 (p2) of the solder connection portions 29.

As shown in FIGS. 12 and 13, the thin-film solar cell module 100a is so formed that the pitch p1 (p2) of the solder connection portions 29 is substantially twice the pitch p4 of the recess portions 301b (projecting portions 301a) of the filler 301. Solder connection portions 29b are deviated from solder connection portions 29a by substantially half (about p4/2) the pitch p4 of the recess portions 301b of the filler 301 in a direction Y (see FIG. 4). Thus, the solder connection portions 29a on the side of the thin-film solar cell module 100a along arrow X1 (see FIG. 4) are opposed to the recess portions 301b of the filler 301, as shown in FIG. 12. Further, the solder connection portions 29b on the side of the thin-film solar cell module 100a along arrow X2 (see FIG. 4) are opposed to the projecting portions 301a of the filler 301, as shown in FIG. 13.

The remaining structure and the remaining effects of the second embodiment are similar to those of the aforementioned first embodiment.

### Third Embodiment

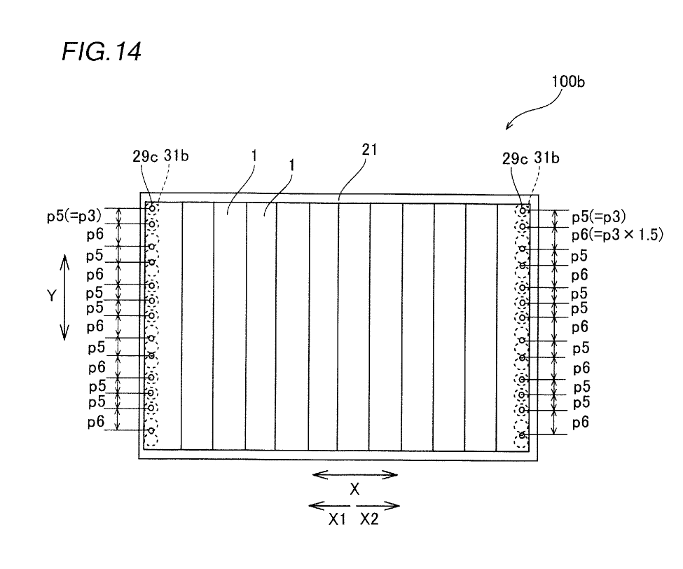

A thin-film solar cell module 100b according to a third embodiment of the present invention is now described with reference to FIG. 14. In the thin-film solar cell module 100b according to the third embodiment, the pitches of a plurality of solder connection portions 29c are different from each other, dissimilarly to the aforementioned first embodiment in which the pitch p1 (p2) of the solder connection portions 29a (solder connection portions 29b) is constant.

In the thin-film solar cell module 100b, the plurality of solder connection portions 29c provided on the sides of along arrows X1 and X2 respectively are so arranged that the pitches (p5 and p6) thereof are different from each other, as shown in FIG. 14. The pitch p5 of the solder connection portions 29c is substantially equal to the pitch p3 of recess portions 31b of a filler 31. The pitch p6 of the solder connection portions 29c is substantially 1.5 times the pitch p3 of the recess portions 31b of the filler 31. Thus, the plurality of solder connection portions 29c are so arranged that central portions of partial solder connection portions 29c do not align with central portions of the recess portions 31b of the filler 31 in plan view. In other words, the plurality of solder connection portions 29c provided along arrows X1 and X2 include those opposed to the recess portions 31b of the filler 31 and those opposed to the projecting portions 31a of the filler 31 respectively. The solder connection portions 29c are examples of the “conducting portions” in the present invention.

The remaining structure of the third embodiment is similar to that of the aforementioned first embodiment.

The thin-film solar cell module 100b according to the third embodiment of the present invention can attain the following effect:

(5) The plurality of solder connection portions 29c are so arranged that the pitches thereof are different from each other in those provided along arrow X1 (X2). Even if positions for forming the plurality of solder connection portions 29c are deviated in the direction Y, therefore, the solder connection portions 29c can be inhibited from being accidentally opposed to and blocking the recess portions 31b of the filler 31, dissimilarly to a case where the plurality of solder connection portions 29c are at a pitch substantially integral times the pitch of the recess portions 31b of the filler 31. Consequently, the solder connection portions 29c can be inhibited from blocking the recess portions 31b of the filler 31 on both sides along arrows X1 and X2.

### Fourth Embodiment

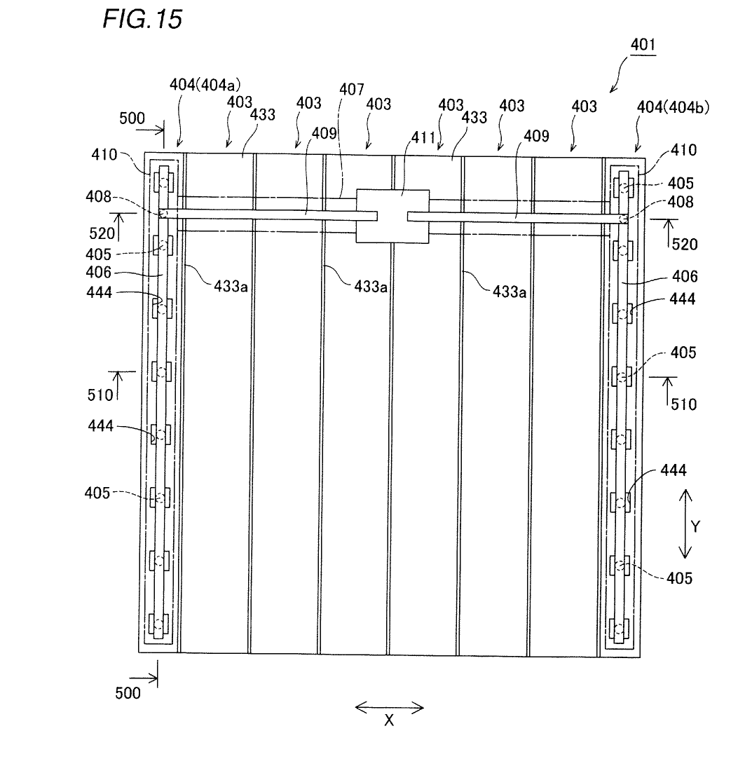

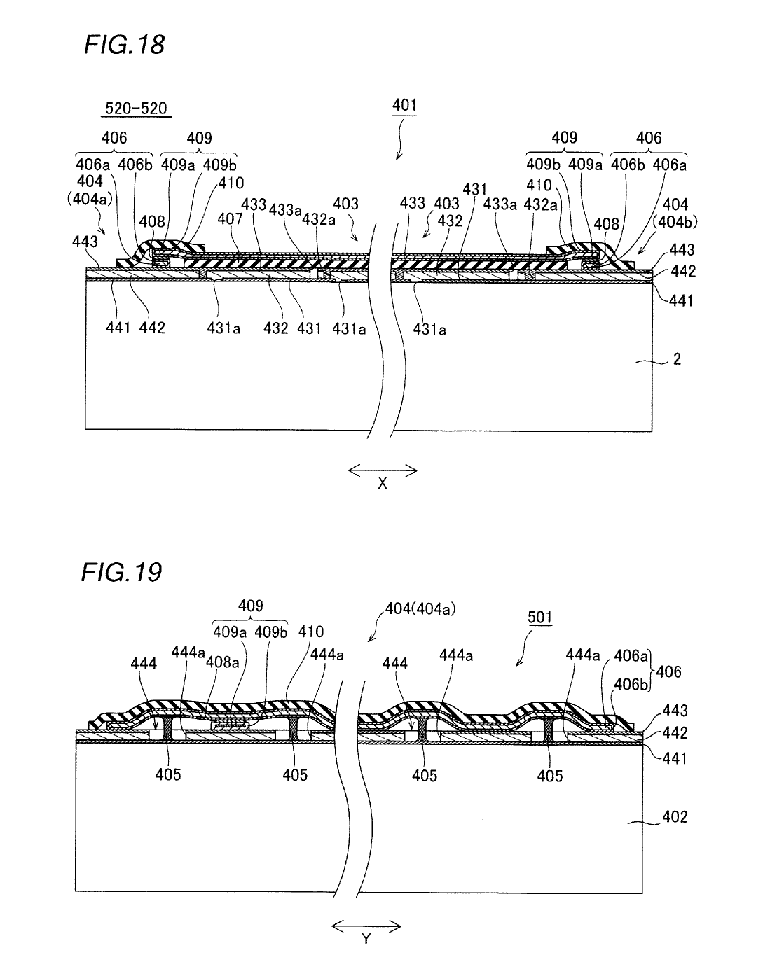

The structure of an integrated thin-film solar cell module 401 according to a fourth embodiment of the present invention is now described with reference to FIGS. 15 to 18.

A thin-film solar cell module comprising extraction electrodes for extracting electricity generated in a power generating portion and extraction wires bonded to the extraction electrodes by fusion portions in order to extract electricity from the extraction electrodes is known in general. In general, a thin-film solar cell module provided with a plurality of thin-film solar cells including surface electrodes formed on the surface of a glass substrate, photoelectric conversion layers formed on the surfaces of the surface electrodes and rear electrodes formed on the surfaces of the photoelectric conversion layers is disclosed. The plurality of thin-film solar cells are arranged in a prescribed direction and connected in series with each other, to constitute a power generating portion. The thin-film solar cell module is also provided with electricity extraction portions having connection portions connected to those of the thin-film solar cells located on end portions of the power generating portion, in order to extract electricity generated in the thin-film solar cells. Extraction electrodes are arranged above the connection portions of the electricity extraction portions, while the lower surfaces of the extraction electrodes and the connection portions are bonded to each other through first solder members. In general, extraction wires for extracting electricity from the extraction electrodes are bonded to the upper surfaces of the extraction electrodes by second solder members. The extraction wires and the extraction electrodes are heated while the extraction electrodes are bonded to the connection portions by the first solder members, whereby the extraction wires are bonded to the extraction electrodes through the second solder members.

In general, the positions of the extraction electrodes bonded to the extraction wires are not particularly taken into consideration. If the extraction wires and the extraction electrodes are bonded to each other on regions overlapping those provided with the first solder members in plan view, however, heat is also applied to the first solder members bonding the connection portions and the extraction electrodes to each other when the second solder members are heated and melted for bonding the extraction wires and the extraction electrodes to each other, and hence the first solder members are disadvantageously remelted. In this case, the extraction electrodes are easily separated from the connection portions due to the remelting of the first solder members, and hence the reliability of the thin-film solar cell module is disadvantageously reduced. The fourth embodiment has been proposed in order to solve the aforementioned problems.

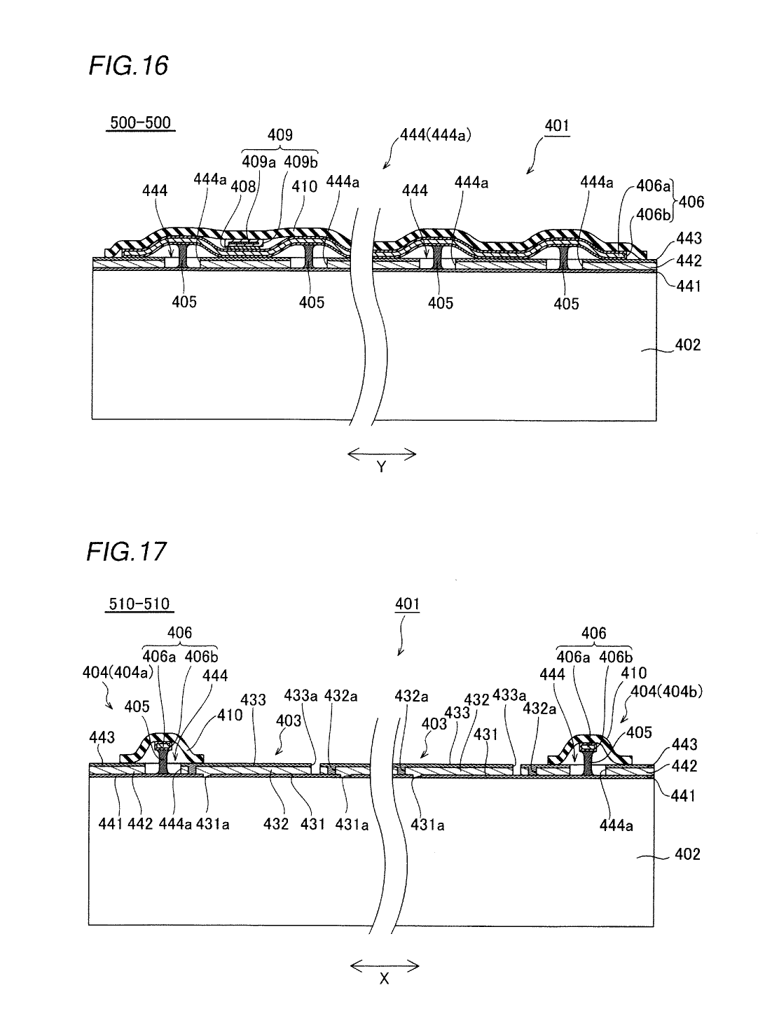

The integrated thin-film solar cell module 401 according to the fourth embodiment comprises a substrate 402 (see FIGS. 16 to 18) provided on an incidence side, a plurality of thin-film solar cells 403 formed on the surface of the substrate 402 and connected in series with each other in a direction X, electricity extraction portions 404 formed on the surface of the substrate 402 and connected to the thin-film solar cells 403 arranged on both end portions in the direction X, and a pair of tab electrodes 406 connected with the electricity extraction portions 404 by solder members 405 for extracting electricity generated in the thin-film solar cells 403, as shown in FIGS. 15 to 18. The thin-film solar cell module 401 further comprises an insulating tape 407 provided to cover the upper surfaces of the thin-film solar cells 403, a pair of tab wires 409 bonded to the pair of tab electrodes 406 through solder members 408 respectively, a pair of insulating tapes 410 provided to cover the tab electrodes 406 etc. and a terminal box 411 (see FIG. 15) connected to the tab wires 409. A back sheet (not shown) made of glass is bonded to the rear surface of the thin-film solar cell module 401. Each thin-film solar cell 403 is in the form of a rectangle having long sides in a direction Y orthogonal to the direction X in plan view. The electricity extraction portions 404 are formed to extend in the direction Y in plan view.

The substrate 402 has an insulating surface, and is made of glass having light transmission properties. This substrate 402 has a thickness of at least about 1 mm and not more than about 5 mm.

The thin-film solar cells 403 include surface electrodes 431 formed on the surface of the substrate 402, photoelectric conversion units 432 formed on the surfaces of the surface electrodes 431 and rear electrodes 433 formed on the surfaces of the photoelectric conversion units 432. The photoelectric conversion units 432 are examples of the “photoelectric conversion layer” in the present invention.

The surface electrodes 431, each having a thickness of about 800 nm, are made of a transparent conductive oxide (TCO) such as tin oxide (SnO₂), zinc oxide (ZnO) or indium tin oxide (ITO) having conductivity and light transmission properties. The surface electrodes 431 of the thin-film solar cells 403 adjacent to each other are isolated from each other by open groove portions 431a.

The photoelectric conversion units 432 are made of a p-i-n amorphous silicon semiconductor. The photoelectric conversion units 432 made of the p-i-n amorphous silicon semiconductor are constituted of p-type hydrogenated amorphous silicon carbide (a-SiC:H) layers each having a thickness of at least about 10 nm and not more than about 20 nm, i-type hydrogenated amorphous silicon (a-Si:H) layers each having a thickness of at least about 250 nm and not more than about 350 nm and n-type hydrogenated amorphous silicon layers each having a thickness of at least about 20 nm and not more than about 30 nm. The photoelectric conversion units 432 of the thin-film solar cells 403 adjacent each other are isolated from each other by open groove portions 432a.

The rear electrodes 433 are formed on the upper surfaces of the photoelectric conversion units 432. The rear electrodes 433, each having a thickness of at least about 200 nm and not more than about 400 nm, are made of a metallic material mainly composed of silver (Ag). The rear electrodes 433 have a function of reflecting light entering the photoelectric conversion units 432 from the lower surface side of the substrate 402 and reaching the rear electrodes 433 thereby reintroducing the same into the photoelectric conversion units 432. The rear electrodes 433 of the thin-film solar cells 403 adjacent to each other are isolated by open groove portions 433a formed in regions corresponding to the open groove portions 432a. The open groove portions 433a further isolate the photoelectric conversion units 432 from each other, and reach the surfaces of the surface electrodes 431. Films of TCO (ZnO or ITO, for example) each having a thickness of about 100 nm may be formed between the photoelectric conversion units 423 and the rear electrodes 433 (between semiconductor layers 442 described later and the rear electrodes 433).

The surface electrodes 431 of first ones of the thin-film solar cells 403 adjacent to each other and the rear electrodes 433 of second ones of these thin-film solar cells 403 are so connected with each other as to constitute the plurality of integrated thin-film solar cells 403 connected in series with each other. The plurality of thin-film solar cells 403 constitute the “power generating portion” in the present invention.

The electricity extraction portions 404 consist of an electricity extraction portion 404a arranged on one end, serving as a positive pole, of the thin-film solar cell module 401 in the direction X and an electricity extraction portion 404b arranged on another end, serving as a negative pole, of the thin-film solar cell module 401 in the direction X. The electricity extraction portions 404 (404a and 404b) include surface electrodes 441 formed on the surface of the substrate 402, the semiconductor layers 442 formed on the surfaces of the surface electrodes 441 and rear electrodes 443 formed on the surfaces of the semiconductor layers 442. The materials for and the thicknesses of the surface electrodes 441, the semiconductor layers 442 and the rear electrodes 443 are similar to the materials for and the thicknesses of the surface electrodes 431, the photoelectric conversion units 432 and the rear electrodes 433 of the thin-film solar cells 403 respectively. The surface electrodes 441 of the electricity extraction portions 404 are formed integrally with the surface electrodes 431 of the thin-film solar cells 403 adjacent thereto. The surface electrodes 441 are examples of the “connection portion” in the present invention.

A plurality of hole-shaped openings 444 are formed in the electricity extraction portions 404 (404a and 404b) to expose the surface electrodes 441 through the rear electrodes 443 and the semiconductor layers 442. The plurality of openings 444 are arranged at prescribed intervals (about 30 mm in the fourth embodiment) in the direction Y. Each opening 44 is in the form of a square of about 4 mm on each side in plan view.

The solder members 405 bonded to the exposed surface electrodes 441 are provided in the openings 444 respectively. In other words, the solder members 405 are plurally provided at prescribed intervals (about 30 mm in the fourth embodiment) in the direction Y in a dotted manner. The solder members 405 are in the form of circles each having a diameter of about 2 mm in plan view. In other words, the solder members 405 each having the diameter of about 2 mm in plan view are arranged in the openings 444 each in the form of the square of about 4 mm on each side. Namely, the width (about 4 mm) of the openings 444 in the direction X is larger than the width (about 2 mm) of the solder members 405 in the direction X, while the width (about 4 mm) of the openings 444 in the direction Y is also larger than the width (about 2 mm) of the solder members 405 in the direction Y. The solder members 405 are arranged on substantially central portions of the openings 444. Thus, the outer peripheral surfaces of the circular solder members 405 are separated from the overall peripheries of inner side surfaces 444a of the square openings 444. The solder members 405 are made of a solder material (trade name: Cerasolzer) easily bondable to the surface electrodes 441 (metal oxide), dissimilarly to an ordinary solder material (material for the solder members 408). The solder members 405 are bonded to the surface electrodes 441 with an ultrasonic soldering iron. The solder members 405 are examples of the “first fusion portion” in the present invention.

The tab electrodes 406 for extracting electricity are provided to extend in the direction Y over the plurality of openings 444, and bonded to the solder members 405 provided in the plurality of openings 444 respectively. The tab electrodes 406 are flatly formed by covering (plating) the surfaces of core wires 406a made of Cu with solder members 406b, each in a thickness of about 150 μm. The width (about 2 mm in the fourth embodiment) of the tab electrodes 406 in the direction X is smaller than the width of the openings 444 in the direction X. The solder members 405 are arranged to bond the surface electrodes 441 and the tab electrodes 406 to each other in the state separated from the overall peripheries of the inner side surfaces 444a of the openings 444.

According to the fourth embodiment, the lower surfaces of the tab electrodes 406 and the solder members 405 are bonded to each other on a vertical position protruding upward beyond the upper surface of the power generating portion (upper surfaces of the rear electrodes 443), as shown in FIG. 16. In portions other than the bonded portions of the tab electrodes 406 and the solder members 405, the lower surfaces of the tan electrodes 406 are in contact with and supported by the upper surfaces of the rear electrodes 443. In other words, the lower surfaces of the tab electrodes 406 are located on the same vertical position as the upper surface of the power generating portion (upper surfaces of the rear electrodes 443). Therefore, portions of the upper surfaces of the tab electrodes 406 bonded to the solder members 405 protrude upward beyond the remaining portions. The tab electrodes 406 are examples of the “extraction electrodes” in the present invention.

The tab wires 409, each having a thickness of about 100 μm and a width of about 5 mm, are formed by covering (plating) the surfaces of core wires 409a made of Cu with solder members 409b, similarly to the tab electrodes 406. The tab wires 409 are examples of the “extraction wire” in the present invention. The lower surfaces of end portions of the tab wires 409 and the upper surfaces of the tab electrodes 406 are bonded to each other by the solder members 408. According to the fourth embodiment, the lower surfaces of the end portions of the tab wires 409 and the upper surfaces of the tab electrodes 406 are bonded to each other by the solder members 405 on substantially central positions of regions between pairs of solder members 405 adjacent to each other in plan view. Thus, the solder members 408 are arranged on positions (most separated from the solder members 405) so deviated as not to overlap the solder members 405 (portions of the solder members 405 and the tab electrodes 406 bonded to each other) in plan view. In other words, the solder members 408 are bonded to the tab electrodes 406 on positions of the tab electrodes 406 not protruding upward. The solder members 408 are examples of the “second fusion portion” in the present invention.

The insulating tape 407 is so provided as to cover portions (regions corresponding to the tab wires 409) of the upper surface of the power generating portion in order to prevent the tab wires 409 and the thin-film solar cells 403 (power generating portion) from an electrical short circuit. The insulating tapes 410 are so provided as to cover the openings 444, the solder members 405, the tab electrodes 406 and the tab wires 409 (in the vicinity of the bonded portions of the tab electrodes 406 and the tab wires 409). The insulating tapes 410 inhibit a liquid sealer made of EVA (ethylene vinyl acetate) or the like from entering the spaces between the bonded portions of the surface electrodes 441 and the tab electrodes 406 and those of the tab electrodes 406 and the tab wires 409 when sealing the thin-film solar cells 403, the electricity extraction portions 404, the solder members 405, the tab electrodes 406, the insulating tape 407, the solder members 408, partial tab wires 409 and the insulating tapes 410.

A manufacturing process for the thin-film solar cell module 401 according to the fourth embodiment of the present invention is now described with reference to FIGS. 15 to 18.

First, the thin-film solar cells 403 and the electricity extraction portions 404 are formed on the substrate 402.

More specifically, the surface electrodes 431 and 441, made of tin oxide, each having the thickness of about 800 nm are formed on the upper surface of the substrate 402 having the insulating surface by thermal CVD (chemical vapor deposition).

Then, the opening groove portions 431a are formed by scanning the surface electrodes 431 with fundamental waves of an Nd:YAG laser having a wavelength of 1064 nm, an oscillation frequency of about 20 kHz and average power of about 14.0 W from the side of the substrate 402.

Then, the p-type hydrogenated amorphous silicon carbide layers each having the thickness of at least about 10 nm and not more than about 20 nm, the i-type hydrogenated amorphous silicon layers each having the thickness of at least about 250 nm and not more than about 350 nm and the n-type hydrogenated amorphous silicon layers each having the thickness of at least about 20 nm and not more than about 30 nm are successively formed on the upper surfaces of the surface electrodes 431 and 441 by plasma CVD, thereby forming the photoelectric conversion units 432 and the semiconductor layers 442 made of amorphous silicon semiconductors respectively. Then, the open groove portions 423a are formed to be adjacent to the open groove portions 431a by scanning the photoelectric conversion units 432 with second harmonics of an Nd:YAG laser having a wavelength of about 532 nm, an oscillation frequency of about 12 kHz and average power of about 230 mW from the side of the substrate 402.

Thereafter the rear electrodes 433 and 443, made of the metallic material mainly composed of silver, each having the thickness of at least about 200 nm and not more than about 400 nm are formed on the upper surfaces of the photoelectric conversion units 432 and the semiconductor layers 442. At this time, the rear electrodes 433 are connected with the surface electrodes 431 of the thin-film solar cells 403 adjacent thereto through the opening groove portions 432a, in order to connect the plurality of thin-film solar cells 403 in series with each other. Films of TCO (ZnO or ITO, for example) each having a thickness of about 100 nm may be formed between the photoelectric conversion units 432 and the semiconductor layers 442 and the rear electrodes 433 and 443.

Then, the open groove portions 433a isolating the rear electrodes 433 and the photoelectric conversion units 432 (the rear electrodes 443 and the semiconductor layers 442) from each other are formed to be adjacent to the open groove portions 432a by scanning the rear electrodes 433 with the second harmonics of the Nd:YAG laser having the wavelength of about 532 nm, the oscillation frequency of about 12 kHz and the average power of about 230 mW from the side of the substrate 402. Thus, the thin-film solar cells 403 and the electricity extraction portions 404 are formed on the substrate 402.

Then, the plurality of openings 444 are formed by scanning the electricity extraction portions 404 with the second harmonics of the Nd:YAG laser having the wavelength of about 532 nm, the oscillation frequency of about 12 kHz and the average power of about 230 mW from the side of the substrate 402.

Thereafter the surface electrodes 441 exposed from the openings 444 and the solder members 405 are bonded to each other with an ultrasonic soldering iron (not shown) in the openings 444 respectively. Thereafter the tab electrodes 406 are arranged to extend over the plurality of openings 444 as shown in FIGS. 15 and 16, and bonded to the solder members 405 by heating the solder members 405 provided in the openings 444 with a soldering iron (not shown) from above the tab electrodes 406.

Thereafter the insulating tape 407 is bonded to cover the upper surfaces of the thin-film solar cells 403 (power generating portion) (upper surfaces of the rear electrodes 433), as shown in FIG. 15. End portions of the pair of tab wires 409 are arranged on the pair of tab electrodes 406 through the solder members 408 respectively. According to the fourth embodiment, the end portions of the tab wires 409 are arranged on substantially central positions of the solder members 405 adjacent to each other in plan view. Then, prescribed portions of the tab electrodes 406 (substantially central positions of the solder members 405 adjacent to each other in plan view) and the end portions of the tab wires 409 are bonded to each other by the solder members 408 by heating the tab wires 409 with a soldering iron (not shown) from the sides of the upper surfaces thereof, as shown in FIGS. 15, 16 and 18. Thereafter the insulating tapes 410 are bonded to cover the upper surfaces of the tab electrodes 406 and the tab wires 409, as shown in FIGS. 15 to 18. Finally, the thin-film solar cells 403, the electricity extraction portions 404, the solder members 405, the tab electrodes 406, the insulating tape 407, the solder members 408, partial tab wires 409 and the insulating tapes 410 are sealed with the sealer made of EVA or the like, and the back sheet (not shown) is bonded thereto.

The thin-film solar cell module 401 according to the fourth embodiment is formed in the aforementioned manner.

The thin-film solar cell module 401 according to the fourth embodiment can attain the following effects:

(6) The tab electrodes 406 and the tab wires 409 are bonded to each other by the solder members 408 on positions so deviated as not to overlap the solder members 405 in plan view. When the tab electrodes 406 and the tab wires 409 are bonded to each other by heating and melting the solder members 408, therefore, heated positions can be separated from the solder members 405. Thus, the solder members 405 bonding the surface electrodes 441 and the tab electrodes 406 to each other can be prevented from application of heat, to be prevented from remelting. Consequently, the tab electrodes 406 can be inhibited from being easily separated, whereby reduction in reliability of the thin-film solar cell module 401 can be suppressed.

(7) The tab electrodes 406 and the tab wires 409 are bonded to each other on positions between the pairs of solder members 405 adjacent to each other in plan view, whereby the heated positions can be easily separated from the solder members 405 when the tab electrodes 406 and the tab wires 409 are bonded to each other by heating and melting the solder members 408.

(8) The tab electrodes 406 and the tab wires 409 are bonded to each other on substantially central positions between the pairs of solder members 405 adjacent to each other in plan view so that the solder members 408 can be melted for bonding the tab electrodes 406 and the tab wires 409 to each other by heating the solder members 408 on positions most separated from the solder members 405, whereby the solder members 405 can be more effectively inhibited from remelting.

(9) The tab wires 409 and the tab electrodes 406 are bonded to each other on positions so deviated as not to overlap the upwardly protruding bonded portions of the tab electrodes 406 and the solder members 405 in plan view, whereby portions (low portions) of the tab electrodes 406 not upwardly protruding and the tab wires 409 can be bonded to each other. Thus, the thicknesses of the tab wires 409 and the solder members 408 are added to the low portions of the tab electrodes 406, whereby the vertical difference between the highest portion and the lowest portion of the thin-film solar cell module 401 can be reduced before lamination. Thus, the lamination can be easily performed, and the thickness of the sealer made of EVA or the like can be reduced.

(10) The tab wires 409 can be easily bonded to the tab electrodes 406 by bonding the solder members 405 to the lower surfaces of the tab electrodes 406 and bonding the lower surfaces of the tab wires 409 to the upper surfaces of the tab electrodes 406 with the solder members 408.

(11) The solder members 405 for bonding the surface electrodes 441 and the tab electrodes 406 to each other are separated from the inner side surfaces 444a of the openings 444 of the electricity extraction portions 404. Even if the electricity extraction portions 404 are separated on the interfaces between the surface electrodes 441 and the semiconductor layers 442 or the interfaces between the semiconductor layers 442 and the rear electrodes 443, therefore, the solder members 405 can be prevented from application of the separating force. Thus, the surface electrodes 441 and the solder members 405 can be inhibited from separation on the interfaces therebetween, whereby reduction in reliability of the thin-film solar cell module 401 can be suppressed.

(12) The plurality of openings 444 are provided on the electricity extraction portions 404 at the prescribed intervals along the direction Y corresponding to the extensional direction of the tab electrodes 406, and the surface electrodes 441 and the tab electrodes 406 are bonded to each other by the solder members 405 on a plurality of portions through the plurality of openings 444 respectively. Thus, portions (the semiconductor layers 442 and the rear electrodes 443) of the electricity extraction portions 404 other than the openings 444 are arranged on regions between the bonded portions (the openings 444) of the tab electrodes 406 and the surface electrodes 441. Therefore, the tab electrodes 406 can be supported from below by the portions (the semiconductor layers 442 and the rear electrodes 443) of the electricity extraction portions 404 other than the openings 444 in the regions between the bonded portions (the openings 444) of the tab electrodes 406 and the surface electrodes 441. Even if force downwardly pressing the tab electrodes 406 is externally applied, therefore, the force can be received from below since the tab electrodes 406 are supported from below on the regions other than the bonded portions. Thus, the force can be inhibited from concentrated application to the bonded portions. Therefore, force applied to the tab electrodes 406 and the solder members 405 on the bonded portions can be reduced, whereby the surface electrodes 441 and the solder members 405 can be inhibited from separation on the interfaces therebetween. Consequently, reduction in reliability of the thin-film solar cell module 401 can be suppressed.

### Fifth Embodiment

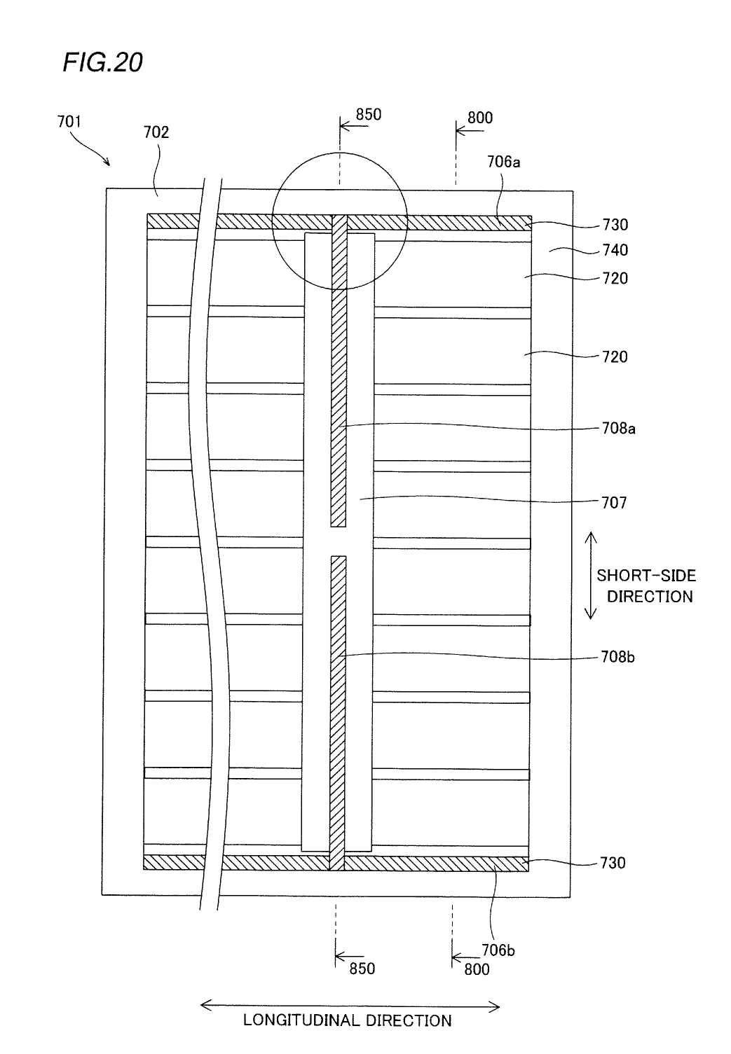

A solar cell module 701 according to a fifth embodiment of the present invention is now described with reference to FIGS. 20 to 22.

In a conventional solar cell module, a plurality of photoelectric conversion elements are formed on a substrate. The photoelectric conversion elements are constituted of laminates obtained by successively stacking transparent conductive films, photoelectric conversion units and rear electrodes from the side closer to the substrate. The photoelectric conversion elements are so formed that adjacent ones thereof are electrically connected in series with each other by the transparent conductive films. In order to collect power generated in the plurality of photoelectric conversion elements, bus regions are provided on terminal end portions of the plurality of photoelectric conversion elements connected with each other. In the bus regions, electrodes consisting of solder-plated copper foils are mounted on the rear electrodes, while wires for extracting the collected power are mounted on the electrodes. The wires are connected to a terminal box. Insulating members are arranged between the wires and the rear electrodes of the photoelectric conversion elements, in order to prevent a short circuit from the rear electrodes to the wires.

Fillers made of EVA (ethylene vinyl acetate) are provided between the plurality of photoelectric conversion elements and the insulating members and between the insulating members and the wires, to fix the wires and the insulating members. The fillers have thicknesses capable of filling up the spaces between the wires and the insulating members.

The conventional solar cell module uses the fillers having large thicknesses, and hence laminates obtained by successively stacking the fillers, the insulating members and the fillers are larger in thickness than the electrodes. Consequently, the upper surfaces of the laminates obtained by successively stacking the fillers, the insulating members and the fillers and the upper surfaces of the electrodes are different in height from each other, and hence the wires connected to the electrodes must be deformed (bent) in portions corresponding to the spaces between the electrodes and the insulating members. Thus, there is a possibility that the wires float on connected surfaces of the electrodes and the wires on the side adjacent to the photoelectric conversion elements due to elasticity thereof. In this case, the electrodes and the wires are not bonded to each other but cause defective connection.

A structure obtained by arranging only insulating members between rear electrodes of photoelectric conversion elements and wires is also disclosed in general. According to this structure, the insulating members are smaller in thickness than the electrodes, and hence the upper surfaces of the insulating members and those of the electrodes are different in height from each other. Therefore, the wires must be deformed (bent) in portions corresponding to the spaces between the electrodes and the insulating members. When the wires are deformed and arranged on the insulating members, portions of the wires positioned on the insulating members provided on the side adjacent to the electrodes may not be supported by the insulating members but float. If external force is applied to the portions of the wires not supported by the insulating members, therefore, the wires may be damaged or defective connection may be caused on the connected portions of the electrodes and the wires. The fifth embodiment has been proposed in order to solve the aforementioned problems.

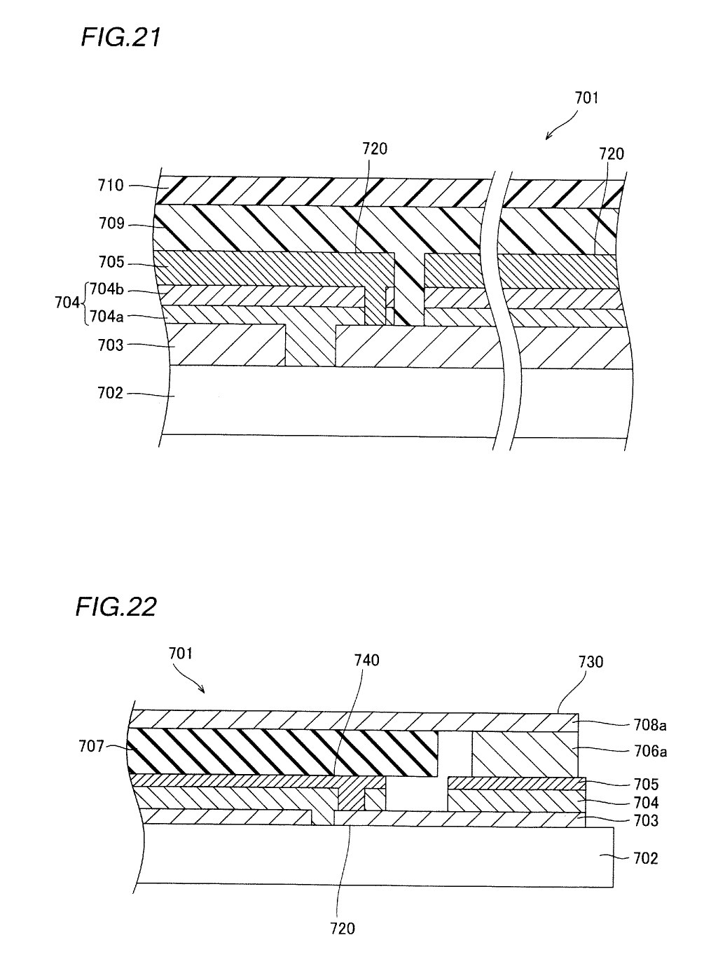

In the solar cell module 701 according to the fifth embodiment, a plurality of photoelectric conversion elements 720 are arranged on a substrate 702, as shown in FIG. 21. The plurality of photoelectric conversion elements 720 are formed by successively stacking transparent conductive films 703, photoelectric conversion units 704a and 704b and rear electrodes 705 on the substrate 702.

The substrate 702, constituted of a light-transmitting member made of glass or the like, is a single substrate for solar cells. The plurality of photoelectric conversion elements 720 are formed on a rear side of the substrate 702 opposite to an incidence side.

The transparent conductive films 703 (first electrodes) are provided in the form of strips on the substrate 702 in plan view. According to the fifth embodiment, ZnO having high light transmission properties, low resistance and excellent plasticity and requiring a low cost is employed as the material for the transparent conductive films 703.

The photoelectric conversion units 704a and 704b are provided on the transparent conductive films 703 in the form of strips. The photoelectric conversion units 704a and 704b are constituted of amorphous silicon semiconductors and microcrystalline silicon semiconductors respectively. In this specification, the term “microcrystalline” denotes not only a complete crystalline state but also a state partially including a noncrystalline state.

The rear electrodes 705 (second electrodes) are made of a conductive material such as Ag, and provided on the photoelectric conversion units 704b in the form of strips. Layers made of a transparent conductive material may be interposed between the rear electrodes 705 and the photoelectric conversion units 704b.

The transparent conductive films 703 of first ones of the photoelectric conversion elements 720, consisting of the photoelectric conversion units 704a and 704b, adjacent to each other are connected to the rear electrodes 705 of second ones of these photoelectric conversion elements 720, whereby the photoelectric conversion elements 720 are electrically connected in series with each other. The photoelectric conversion elements 720 are in the form of strips extending in the longitudinal direction.

In the specification, a term “short-side direction” denotes a direction where the solar cell module 701 is electrically connected in series. In the specification, further, the term “longitudinal direction” denotes a direction substantially orthogonal to the direction where the solar cell module 701 is electrically connected in series.

Electrodes 706a and 706b consisting of solder-plated copper foils are formed on bus regions 730 positioned on both ends of the photoelectric conversion elements 720 in the short-side direction of the substrate 702 in order to extract power generated in the plurality of photoelectric conversion elements 720, as shown in FIG. 20. The solder-plated copper foils which are base materials forming the electrodes 706a and 706b are about 40 μm to about 120 μm, particularly preferably about 80 μm in thickness.

An insulating adhesive member 707 is arranged to cover an upper portion of a power generating region 740 consisting of the plurality of photoelectric conversion elements 720 between the electrodes 706a and 706b. The insulating adhesive member 707 is made of PET. The insulating adhesive member 707 has a thickness (about 40 μm to about 120 μm) substantially identical to the total thickness of the electrodes 706a and 706b and solder members (not shown) fixing the electrodes 706a and 706b, and particularly preferably has a thickness of about 50 μm to about 80 μm. Further, the insulating adhesive member 707 preferably has a white surface adjacent to the photoelectric conversion elements 720. Thus, light incident from the spaces between the photoelectric conversion elements 720 adjacent to each other can be more excellently scattered. The quantity of power generated in the photoelectric conversion elements 720 can be increased by introducing the scattered light into the photoelectric conversion elements 720.

Wires 708a and 708b are connected to the electrodes 706a and 706b positioned on both ends of the plurality of photoelectric conversion elements 720 in the short-side direction respectively. The wires 708a and 708b consist of solder-plated copper foils, and are arranged to extend on the insulating adhesive member 707.

A filler 709 made of EVA (ethylene vinyl acetate) or the like for sealing the plurality of photoelectric conversion elements 720 and a rear surface protective member 710 (protective material) made of PET/Al foil/PET or the like are provided on the substrate 702. The solar cell module 701 is completed by extracting first end portions of the wires 708a and 708b not connected to the electrodes 706a and 706b from openings provided in the filler 709 and the rear surface protective member 710 and connecting the same to a terminal box (not shown).

While the photoelectric conversion units 704a and 704b are formed by successively stacking the amorphous silicon semiconductors and the microcrystalline silicon semiconductors respectively according to the fifth embodiment, a similar effect can also be attained by employing single layers or at least triple layers of microcrystalline and/or amorphous photoelectric conversion units.

Intermediate layers made of ZnO, SnO₂, SiO₂ or MgZnO may be provided between the photoelectric conversion units 704a and 704b, for improving optical properties.

The transparent conductive films 703 may be constituted of laminates of one or a plurality of materials selected from metal oxides such as In₂O₃, SnO₂, TiO₂ and Zn₂SnO₄, in place of ZnO employed in the fifth embodiment.

The electrodes 706a and 706b may be provided not on the end portions of the substrate 702, but on portions close to a central portion.

The filler 709 may be made of ethylene-based resin such as EEA, PVB, silicon, urethane, acrylic or epoxy resin, in place of EVA.

The rear surface protective member 710 may be constituted of a structure obtained by holding a metal foil between films of fluorine-based resin (ETFE, PVDF or PCTFE), PC or glass, a SUS plate or a steel plate. A surface of the rear surface protective member 710 opposed to the photoelectric conversion elements 720 is preferably formed by a white surface. Thus, light incident from the spaces between the photoelectric conversion elements 720 adjacent to each other can be more excellently scattered. The quantity of power generation in the photoelectric conversion elements 720 can be increased by introducing the scattered light into the photoelectric conversion elements 720. The colors of the rear surface protective member 717 and the insulating adhesive member 707 are preferably identical to each other. Thus, the color tones of portions seen through the spaces between the photoelectric conversion elements 720 of the solar cell module 701 as viewed from the side of the substrate 702 can be rendered identical to each other, and designability of the solar cell module 701 can be improved.

An aluminum frame can be mounted on end portions of the solar cell module 701 with butyl rubber or the like.

Connected portions of the electrodes 706a and 706b and the wires 708a and 708b characterizing the fifth embodiment are now described in detail with reference to FIG. 22.

In the bus regions 730, the electrodes 706a and 706b consisting of the solder-plated copper foils are fixed onto the rear electrodes 705 with solder members (not shown). According to the fifth embodiment, rectangular solder-plated copper foils having shapes corresponding to those of the bus regions 730 are employed as the electrodes 706a and 706b. The transparent conductive films 703, the photoelectric conversion units 704a and 704b and the rear electrodes 705 in the bus regions 730 are stacked similarly to those in the photoelectric conversion elements 720. The wires 708a and 708b extend in the short-side direction, and are so arranged that first end portions thereof cover the overall connected surfaces of the electrodes 706a and 706b. The wires 708a and 708b are bonded to the connected surfaces (upper surfaces) of the electrodes 706a and 706b with solder members.

In the power generating region 740, on the other hand, the insulating adhesive member 707 is arranged between the rear electrodes 705 and the wires 708a and 708b. The insulating adhesive member 707 is bonded to the rear electrodes 705. In the insulating adhesive member 707, the length in the longitudinal direction is larger than that of the wires 708a and 708b in the longitudinal direction, while the length in the short-side direction is larger than that of the power generating region 740 in the short-side direction. The insulating adhesive member 707 is so arranged between the rear electrodes 705 and the wires 708a and 708b that the rear electrodes 750 of the power generating region 740 and the wires 708a and 708b are not in contact with each other. Thus, the insulating adhesive member 707 prevents an electrical short circuit between the wires 708a and 708b and the rear electrodes 705.

According to the fifth embodiment, the thicknesses of the electrodes 706a and 706b and the insulating adhesive member 707 are rendered substantially equal to each other, so that surfaces of the electrodes 706a and 706b connected with the wires 708a and 708b and a surface of the insulating adhesive member 707 opposed to the wires 708a and 708b are substantially flush with each other (located on substantially identical vertical positions). When arranged to cover the upper portion of the insulating adhesive member 707, therefore, the wires 708a and 708b connected to the electrodes 706a and 706b may not be remarkably deformed in portions corresponding to the space between the electrodes 706a and 706b and the adhesive insulating member 707.

Therefore, the wires 708a and 708b and the electrodes 706a and 706b can be easily bonded and fixed to each other by the solder members on the overall connected surfaces opposed to each other, to attain excellent connection with large contact areas. The upper surfaces of the adhesive insulating member 707 and the electrodes 706a and 706b are flush with each other (located on the same vertical positions), whereby portions of the wires 708a and 708b positioned between the adhesive insulating member 707 and the electrodes 706a and 706b are not easily deformed even if external force is applied from above the wires 708a and 708b. Thus, defective connection between the electrodes 706a and 706b and the wires 708a and 708b or damages of the wires 708a and 708b can be prevented, and reliability of the solar cell module 701 can be improved.

According to the fifth embodiment, as hereinabove described, the reliability of the solar cell module 701 can be improved by preventing defective connection between the electrodes 706a and 706b and the wires 708a and 708b or damages of the wires 708a and 708b.

Although the present invention has been described and illustrated in detail, it is clearly understood that the same is by way of illustration and example only and is not to be taken by way of limitation, the spirit and scope of the present invention being limited only by the terms of the appended claims.

While the present invention is applied to amorphous silicon semiconductor layers in each of the aforementioned first to third embodiments, the present invention is not restricted to this. The present invention may alternatively be applied to crystalline silicon semiconductor layers, for example. The present invention may also be applied to tandem-type semiconductor layers formed by stacking amorphous silicon semiconductor layers and microcrystalline silicon semiconductor layers.

While the solder connection portions are employed as the conducting portions in the present invention in each of the aforementioned first to third embodiments, the present invention is not restricted to this. Alternatively, conducting portions made of conductive resin, for example, other than the solder connection portions may be employed.

While the p-i-n semiconductor layers are employed in each of the aforementioned first to third embodiments, the present invention is not restricted to this. Alternatively, p-n semiconductor layers may be employed, for example.

While the pitch of the solder connection portions is one time as long as the pitch of the recess portions of the filler in the aforementioned first embodiment and the pitch of the solder connection portions is twice the pitch of the recess portions of the filler in the aforementioned second embodiment, the present invention is not restricted to this. The pitch of the solder connection portions may simply be substantially integral times the pitch of the recess portions, for example. Alternatively, the pitch of the solder connection portions may be substantially one-integerth (one-half, one-third or the like) of the pitch of the recess portions of the filler.

While the solder connection portions arranged along arrow X2 are deviated from the solder connection portions arranged along arrow X1 by substantially half the pitch of the recess portions of the filler in the extensional direction (direction Y) of the extraction electrodes in each of the aforementioned first and second embodiments, the present invention is not restricted to this. According to the present invention, the solder connection portions may be so deviated that central portions of partial ones of the plurality of solder connection portions do not align with the central portions of the recess portions of the filler in plan view.

While the tab electrodes 406 and the tab wires 409 are bonded to each other by the solder members 408 on substantially central positions between the solder members 405 adjacent to each other in the aforementioned fourth embodiment, the present invention is not restricted to this, but the tab electrodes 406 and the tab wires 409 may be bonded to each other by the solder members 408 on positions so deviated as not to overlap the solder members 405 in plan view.

While the solder members 408 are arranged on positions deviated from the solder members 405 in the extensional direction (direction Y) of the tab electrodes 406 in plan view in the aforementioned fourth embodiment, the present invention is not restricted to this, but the solder members 408 may alternatively be arranged on positions deviated from the solder members 408 in the direction X in plan view.

While the surface electrodes 441 and the tab electrodes 406 are bonded to each other by the plurality of solder members 405 arranged in the dotted manner in the aforementioned fourth embodiment, the present invention is not restricted to this, but the surface electrodes 441 and the tab electrodes 406 may alternatively be bonded to each other by arranging linearly arranged solder members (first fusion portions) extending in the direction Y at prescribed intervals. When the linear solder members (first fusion portions) are plurally provided at the prescribed intervals, the tab electrodes 406 and the tab wires 409 may be bonded to each other by solder members (second fusion portions) not to overlap the solder members (first fusion portions) in regions between the solder members (first fusion portions) in plan view.

While the tab electrodes 406 and the tab wires 409 are bonded to each other by heating the solder members 408 with the soldering iron in the state holding the solder members 408 between the tab electrodes 406 and the tab wires 409 in the aforementioned fourth embodiment, the present invention is not restricted to this, but the tab electrodes 406 and the tab wires 409 may alternatively be bonded to each other by the plating solder member 406b of the tab electrodes 406 and the plating solder members 409b of the tab wires 409. In this case, the fused plating solder members 406b and 409b on the bonded portions are examples of the “second fusion portion” in the present invention.

While the respective ones of the solder members 405 and 408 are employed as the examples of the “first fusion portion” and the “second fusion portion” in the present invention in the aforementioned fourth embodiment, the present invention is not restricted to this, but fusion members other than the solder members may alternatively be employed as the “first fusion portion” and the “second fusion portion” in the present invention.

While the upper surfaces of the tab electrodes 406 and the lower surfaces of the tab wires 409 are bonded to each other by the solder members 408 in the aforementioned fourth embodiment, the present invention is not restricted to this, but the upper surfaces of the tab electrodes 406 and the lower surfaces of the tab wires 409 may alternatively be bonded to each other by solder members 408a on positions (positions similar to those shown in FIGS. 15 and 16) so deviated as not to overlap the solder members 405 in regions between the solder members 405 in plan view, as in a thin-film solar cell module 501 according to a modification of the fourth embodiment shown in FIG. 19. Also in this case, the tab electrodes 406 can be inhibited from easy separation similarly to the aforementioned fourth embodiment, whereby reduction in reliability of the thin-film solar cell module 501 can be suppressed.

While the openings 444 are square-shaped in the aforementioned fourth embodiment, the present invention is not restricted to this, but the openings 444 may alternatively be in another shape such as a circular shape, an elliptic shape or a rectangular shape.

What is claimed is:

1. A solar cell module comprising:
a plurality of solar cells electrically connected with each other;
extraction electrodes provided on the sides of both end portions of a region where said plurality of solar cells are arranged for extracting power generated in said plurality of solar cells;
a plurality of conducting portions provided between said solar cells and said extraction electrodes along the extensional direction of said extraction electrodes for electrically bonding said solar cells and said extraction electrodes to each other; and
a filler provided to cover said plurality of solar cells and said extraction electrodes, wherein
said plurality of conducting portions include a plurality of first conducting portions regularly provided and arranged on the side of one end portion of said region where said plurality of solar cells are arranged and a plurality of second conducting portions regularly provided and arranged on the side of another end portion of said region where said plurality of solar cells are arranged, and
said plurality of first conducting portions and said plurality of second conducting portions are asymmetrically arranged with respect to a centerline between said plurality of first conducting portions and said plurality of second conducting portions in plan view.

2. The solar cell module according to claim 1, wherein
said filler has irregular surfaces regularly provided on the sides of said plurality of solar cells and said extraction electrodes, and
said plurality of conducting portions are so arranged that central portions of at least partial said plurality of conducting portions do not align with central portions of recess portions of said filler.

3. The solar cell module according to claim 2, wherein
partial said plurality of conducting portions are deviated from said conducting portions opposed to said recess portions of said filler, to be opposed to projecting portions of said filler.

4. The solar cell module according to claim 1, wherein
said filler has irregular surfaces regularly provided on the sides of said plurality of solar cells and said extraction electrodes,
the pitches of said plurality of first conducting portions and said plurality of second conducting portions are substantially integral times the pitch of recess portions of said filler or substantially one-integerth of the pitch of said recess portions of said filler,
said plurality of first conducting portions and said plurality of second conducting portions are linearly arranged along the extensional direction of said extraction electrodes respectively, and the pitch of said plurality of first conducting portions and the pitch of said plurality of second conducting portions are substantially equal to each other, and
said plurality of first conducting portions are deviated from said plurality of second conducting portions by a prescribed length in the extensional direction of said extraction electrodes.

5. The solar cell module according to claim 4, wherein
said plurality of first conducting portions are deviated from said plurality of second conducting portions by a length substantially half the pitch of said recess portions of said filler in the extensional direction of said extraction electrodes.

6. A method of manufacturing a solar cell module, comprising the steps of:
preparing a plurality of solar cells electrically connected with each other;
forming extraction electrodes for extracting power generated in said plurality of solar cells on the sides of both end portions of a region where said plurality of solar cells are arranged respectively;
forming a plurality of conducting portions for electrically bonding said solar cells and said extraction electrodes to each other between said solar cells and said extraction electrodes along the extensional direction of said extraction electrodes; and
bringing said plurality of solar cells, said extraction electrodes and a filler into close contact with each other by arranging said filler to cover said plurality of solar cells and said extraction electrodes and thereafter performing lamination, wherein
said plurality of conducting portions include a plurality of first conducting portions regularly provided and arranged on the side of one end portion of said region where said plurality of solar cells are arranged and a plurality of second conducting portions regularly provided and arranged on the side of another end portion of said region where said plurality of solar cells are arranged, and
the step of bringing said plurality of solar cells, said extraction electrodes and said filler into close contact with each other includes a step of performing lamination while arranging said filler on said plurality of first conducting portions and said plurality of second conducting portions asymmetrically arranged with respect to a centerline between said plurality of first conducting portions and said plurality of second conducting portions in plan view.

7. The method of manufacturing a solar cell module according to claim 6, wherein
said filler has irregular surfaces regularly provided on the sides of said plurality of solar cells and said extraction electrodes, and
the step of bringing said plurality of solar cells, said extraction electrodes and said filler into close contact with each other includes a step of performing lamination in a state where said plurality of conducting portions are so arranged that central portions of at least partial said plurality of conducting portions do not align with central portions of recess portions of said filler in plan view.

8. The method of manufacturing a solar cell module according to claim 7, wherein
the step of bringing said plurality of solar cells, said extraction electrodes and said filler into close contact with each other includes a step of performing lamination in a state where partial said plurality of conducting portions are deviated from said conducting portions opposed to said recess portions of said filler to be opposed to projecting portions of said filler.

9. The method of manufacturing a solar cell module according to claim 6, wherein
said filler has irregular surfaces regularly provided on the sides of said plurality of solar cells and said extraction electrodes,
the pitches of said plurality of first conducting portions and said plurality of second conducting portions are substantially integral times the pitch of recess portions of said filler or substantially one-integerth of the pitch of said recess portions of said filler,
said plurality of first conducting portions and said plurality of second conducting portions are linearly arranged along the extensional direction of said extraction electrodes respectively, and the pitch of said plurality of first conducting portions and the pitch of said plurality of second conducting portions are substantially equal to each other, and
said plurality of first conducting portions are deviated from said plurality of second conducting portions by a prescribed length in the extensional direction of said extraction electrodes.

10. The method of manufacturing a solar cell module according to claim 9, wherein
said plurality of first conducting portions are deviated from said plurality of second conducting portions by a length substantially half the pitch of said recess portions of said filler in the extensional direction of said extraction electrodes.

11. A solar cell module comprising:
a substrate;
a power generating portion consisting of a plurality of thin-film solar cells each including a surface electrode formed on said substrate, a photoelectric conversion layer formed on said surface electrode and a rear electrode formed on said photoelectric conversion layer;
an electricity extraction portion including a connection portion connected to said thin-film solar cell positioned on an end portion of said power generating portion;
an extraction electrode formed on said electricity extraction portion for extracting electricity generated by said power generating portion;
a first fusion portion bonding said connection portion and said extraction electrode to each other; and
an extraction wire provided for extracting electricity from said extraction electrode and bonded to said extraction electrode by a second fusion portion on a position deviated from said first fusion portion not to overlap said first fusion portion in plan view.

12. The solar cell module according to claim 11, wherein
said electricity extraction portion is provided with a plurality of said first fusion portions to bond said connection portion and said extraction electrode to each other on a plurality of positions at prescribed intervals along the extensional direction of said extraction electrode, and
said extraction electrode and said extraction wire are bonded to each other on a position between two said first fusion portions adjacent to each other in plan view.

13. The solar cell module according to claim 11, wherein
said first fusion portion is bonded to the lower surface of said extraction electrode on a vertical position protruding upward beyond the upper surface of said power generating portion so that a bonded portion of said extraction electrode corresponding to said first fusion portion protrudes upward, and
said extraction wire is bonded to said extraction electrode on a position so deviated as not to overlap upwardly protruding said bonded portion in plan view.

14. The solar cell module according to claim 11, wherein
said first fusion portion is bonded to the lower surface of said extraction electrode, and
the upper surface of said extraction electrode and the lower surface of said extraction wire are bonded to each other by said second fusion portion.

15. The solar cell module according to claim 11, wherein
said electricity extraction portion has an opening exposing said connection portion, and
said first fusion portion is separated from the inner side surface of said opening, and bonds said connection portion and said extraction electrode to each other through said opening.

16. A solar cell module comprising:
a substrate;
a photoelectric conversion element provided on said substrate;
an electrode arranged on a first surface of said photoelectric conversion element for collecting power;
a wire connected to said electrode on said first surface of said photoelectric conversion element for extracting power from said electrode; and
an insulating adhesive member provided between said photoelectric conversion element and said wire, wherein
a surface of said electrode connected with said wire and a surface of said insulating adhesive member opposed to said wire are flush with each other.

17. The solar cell module according to claim 16, wherein
said surface of said electrode connected with said wire and said surface of said insulating adhesive member opposed to said wire are located on the same vertical position.

18. The solar cell module according to claim 16, wherein
a plurality of said photoelectric conversion elements are arranged on said substrate at intervals, and
a surface of said insulating adhesive member opposed to said first surfaces of said photoelectric conversion element is white.

19. The solar cell module according to claim 16, wherein
said insulating adhesive member has a thickness substantially identical to the thickness of said electrode.

20. The solar cell module according to claim 16, wherein
said insulating adhesive member is formed to extend to a portion in the vicinity of a portion where said electrode and said wire are connected with each other.
